(19) United States
(12) Patent Application Publication
(10) Pub. No.: US 2006/0183261 A1
(43) Pub. Date: Aug. 17, 2006

(54) Method of forming a biological sensor

(76) Inventors: Christie Lee Dudenhoefer, Corvallis, OR (US); John S. Dunfield, Corvallis, OR (US); Lauren Renee Henry, Dallas, OR (US); Craig A. Olbrich, Corvallis, OR (US); Paul Yager, Seattle, WA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/058,145

(22) Filed: Feb. 15, 2005

(51) Int. Cl. H01L 21/00; H01L 21/336; H01L 29/82

(52) U.S. Cl. 438/48; 438/257; 257/414

(57) ABSTRACT

A method of forming a biological sensor on a predetermined area of a substrate. The method includes dispensing a plurality of layers on the predetermined area of the substrate. Each of the plurality of layers is formed of a substantially different fluid having a substantially different function. The dispensing of the layers is accomplished by a drop generating member.

### BACKGROUND

The present disclosure relates generally to forming biological sensors. Genomic evaluation is often used for the detection of various genes or DNA sequences within a genome, specific gene mutation such as single nucleotide polymorphisms (SNP), and mRNA species in biological research, industrial applications, and biomedicine. Often, these large scale techniques include synthesizing or depositing nucleic acid sequences on DNA chips and microarrays. These chips and arrays may be used for detecting the presence of and identifying genes in a genome or evaluating patterns of gene regulation in cells and tissues.

A potential problem in forming such chips or arrays is the inability, in some instances, to form small, localized, unique drop chemistries via a controlled synthesis, which may allow for controlled reaction kinetics and/or controlled concentrations. Some current techniques for forming arrays include pin arrayers, pipettes, and bulk coatings. While pin arrayers may dispense relatively small volumes with good spatial resolution, they are generally not designed to dispense multiple fluids at the same location. Pipettes, in some instances, are generally not capable of dispensing the volumes of interest with accuracy in timing and placement. Bulk coatings generally do not allow for targeted functionalization of specific areas.

Still further, many current techniques use wet chemicals in forming arrays. A potential problem with wet chemicals is that they generally should be used substantially immediately, or they should be stored in refrigeration until use.

Arrays of sensors may also be used in microfluidic devices. These devices are generally capable of analyzing one or more samples for the particular parameter that the array is configured for. One potential problem with such an array may be the general inability to detect a variety of parameters from a single sample.

As such, it would be desirable to provide a substantially controlled method for forming a biological sensor having unique chemistries, wherein the sensor has the ability to be stored substantially stably in ambient conditions. Further, it would be desirable to provide a system in which a sensor may be used that is capable of detecting a variety of parameters from a single sample.

### SUMMARY

A method of forming a sensor on a predetermined area of a substrate is disclosed. The method includes dispensing a plurality of layers on the predetermined area of the substrate. Each of the plurality of layers is formed of a substantially different fluid having a substantially different function. The dispensing of the layers is accomplished by drop generating technology.

### BRIEF DESCRIPTION OF THE DRAWINGS

Objects, features and advantages will become apparent by reference to the following detailed description and drawings, in which like reference numerals correspond to similar, though not necessarily identical components. For the sake of brevity, reference numerals having a previously described function may not necessarily be described in connection with subsequent drawings in which they appear.

FIG. 1 is a schematic view of an embodiment of a diagnostic device having an embodiment of a biological sensor on a substrate;

FIG. 2 is a schematic view of an alternate embodiment of a diagnostic device having an embodiment of a biological sensor on a substrate;

FIG. 3 is a perspective schematic view of a diagnostic device having a plurality of biological sensors present in an array on a substrate; and

FIG. 4 is a schematic view of an embodiment of a microfluidic device.

### DETAILED DESCRIPTION

Embodiment(s) of the biological sensor as defined herein may be used in a consumer-based diagnostic device or system, where the sensor is capable of advantageously diagnosing and/or monitoring a variety of wellness parameters.

The sensor(s) of the present disclosure may be used for detecting the presence of and identifying genes in a genome, and/or evaluating patterns of gene regulation in cells and tissues. Embodiment(s) of the present sensor may also advantageously be used for immunological marking (e.g. in connection with proteins, antibodies and immunoassays). The sensor(s) of the present disclosure may also be used for detecting small molecule antigens, hormones, pharmaceutics, and/or the like. Further, the sensor(s) may be used to form lab cards and/or lab chips using different, individual sensor dots to detect many different analytes of interest, for example from a single biological sample.

It is to be understood that embodiment(s) of the biological sensor may advantageously have small sizes and dried, stable chemistries. Without being bound to any theory, it is believed that the diagnostic test time of an embodiment of the diagnostic device disclosed herein may advantageously be quick, due in part to the small sensor size enabling substantially reduced chemical reaction time, substantially reduced incubation periods, and substantially fast mass transport. Further, an embodiment of the biological sensor has at least three layers, each of which is able to perform a specific, unique function. Still further, embodiments of the biological sensor are dehydrated, thereby advantageously allowing for substantially stable storage of the sensor under ambient conditions until use.

Embodiments of the method of making embodiment(s) of the biological sensor advantageously enable controlled dispensing (via a drop generating technique) of multiple fluids at substantially the same time with close spatial resolution (e.g. at substantially the same location). Without being bound to any theory, it is believed that this allows a user to control the unique chemical reactions that may take place between the dispensed materials. Further, embodiment(s) of the method may advantageously maintain protein conformation and orientation on a surface by allowing a user to control drying and/or evaporation rate(s). Still further, the drop generating technology advantageously allows for control over the synthesis, reaction kinetics, and concentration of the various droplets that make up embodiment(s) of the biological sensor.

Further, a microfluidic device may contain thousands of biological sensors of the present disclosure, each of which is configured to detect a different parameter and/or analyte. Using such a device, a single sample may be divided (and prepared, if desired) upstream of each of the particular sensors, thus advantageously allowing various parameters to be detected from the single sample.

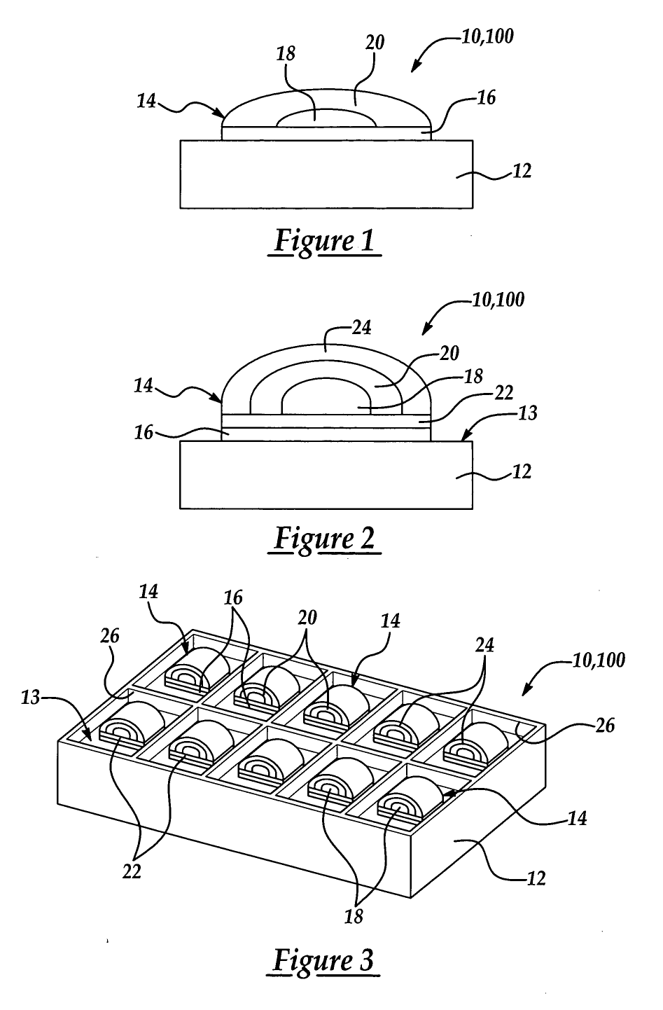

Referring now to FIGS. 1 and 2, two embodiments of a diagnostic device 10 are depicted. Embodiment(s) of the diagnostic device 10 include sensor(s) 14 that may be used to diagnose and/or monitor certain parameters, such as, for example, various wellness parameters. Examples of these wellness parameters include, but are not limited to chronic disease markers, infectious disease markers, molecular biology markers, pharmaceutics, and/or the like. It is to be understood that the embodiment shown in FIGS. 1 and 2 may also be incorporated into a system 100 for diagnosing and/or monitoring such wellness parameters. It is to be further understood that the disclosure herein pertaining specifically to the diagnostic device 10 also pertains to embodiment(s) of the system 100.

As depicted in both FIGS. 1 and 2, the diagnostic device 10 includes a substrate 12 upon which an embodiment of a biological sensor 14 is disposed. It is to be understood that any suitable substrate material may be used. Non-limitative examples of materials that may be selected for the substrate 12 include glass, mylar, poly(methyl methacrylate), coated glass (a non-limitative example of which includes gold coated glass), polystyrene, quartz, plastic materials, silicon, silicon oxides, and/or mixtures/combinations thereof.

In an embodiment, the biological sensor 14 includes at least one layer 18. In an alternate embodiment, sensor 14 includes a plurality of layers, non-limitative examples of which are depicted in FIGS. 1 and 2. As used herein, “plurality of layers” refers to two or more layers. It is to be understood that more than two layers (non-limitative examples of which include three layers 16, 18, 20 and five layers 16, 18, 20, 22, and 24, etc.) may be included in the biological sensor 14. It is to be further understood, however, that any suitable number of layer(s) may be dispensed. In an embodiment, the number of layers dispensed is determined, in part, by the practicality and/or desirability of manufacturing that number of layers. It is to be further understood that any of the layers 16, 18, 20, 22, and 24 that are used may be dispensed such that there is one or more sublayer(s) (not shown) of a particular layer(s) 16,18, 20, 22, and 24.

In both of the embodiments depicted in FIGS. 1 and 2, each of the layers 16, 18, 20, 22 and/or 24 is formed of a substantially different fluid having a substantially different function from each of the other layers. In an embodiment, these functions include, but are not limited to self-assembling, attaching, detecting, preserving, protecting, and/or various combinations thereof.

The fluids dispensed to form the plurality of layers 16, 18, 20, 22, 24 may be biological or non-biological fluids. However, it is to be understood that the layer(s) generally are not formed of a sample to be analyzed. In the non-limitative example depicted in FIG. 1, the fluids selected to form the layers 16, 18, 20 are those fluids capable of forming a self-assembled monolayer 16, a detection molecule/detection molecule layer 18, and a preservative layer 20. In the non-limitative example depicted in FIG. 2, the fluids selected to form the additional layers 22, 24 are those fluids capable of forming a covalent attachment layer 22 and a protective layer 24. In another non-limitative example, the fluids selected to form the biological sensor 14 may be those fluids capable of forming a covalent attachment layer 22, a detection molecule/detection molecule layer 18, and a protective layer 24. It is to be understood that any combination and any number of the layers 16, 18, 20, 22, 24 may be selected as long as the selected layer/one of the selected layers is capable of molecule detection. Further, although example functions/materials are correlated herein with respective layers 16,18, 20, 22, 24, it is to be understood that layers 16,18, 20, 22, 24 may be formed from any suitable materials having any desired function.

The optional self-assembled monolayer 16, shown in both FIGS. 1 and 2, may be dispensed directly on some, or all, of the substrate surface 13 as desired. The self-assembled monolayer 16 may be included in the biological sensor 14, at least in part because of its ability to promote adhesion between the substrate 12 and any additionally deposited layers 18, 20, 22, 24. Further, the fluid dispensed to form the self-assembled monolayer 16 may include molecules capable of self-aligning on predetermined areas of the surface 13 of the substrate 12. It is to be understood that the fluid dispensed to form the self-assembled monolayer 16 may also include molecules that may not form “monolayers,” but are able to substantially modify the substrate surface 13 to substantially improve adhesion and/or performance of the detection molecule layer 18. Non-limitative examples of molecules used for the self-assembled monolayers 16 include strepavidin, biotinylated antibodies, thiols, silane coupling agents (SCA), high molecular weight dextran (non-limitative examples of which range between about 70 kDa and about 100 kDa), polygels, sol gels and/or mixtures thereof.

The optional covalent attachment layer 22 may be deposited directly on some, or all, of the substrate surface 13 (not shown), or it may be deposited on some, or all, of the previously deposited self-assembled monolayer 16 (shown in FIG. 2). Without being bound to any theory, it is believed that the covalent attachment layer 22 may promote adhesion between the layers of the biological sensor 14. In particular, the covalent attachment layer 22 assists in substantially permanently adhering the molecule detection layer 18 to the substrate 12. Without being bound to any theory, it is believed that this occurs when the self-assembled monolayer 16 is present in the biosensor 14, or when the self-assembled monolayer 16 is not present in the biosensor 14. Examples of a suitable covalent attachment layer 22 include, but are not limited to streptavidin, biotin, reactive end groups on silane coupling agents, and combinations thereof.

The detection molecule layer 18 is depicted in both FIGS. 1 and 2. Embodiment(s) of the biological sensor 14 include the detection molecule 18, in part, to advantageously assist in diagnosing and/or monitoring the wellness parameter(s). The detection molecule(s) 18 may substantially capture desired analytes from a test solution or fluid. It is to be understood that the detection molecule layer 18 may be selected, in part, such that the desired analyte may bind thereto. For example, antibodies may be used to bind their antigen molecules, DNA/RNA strands may be used to bind their complementary strand(s), and small molecules may be used to bind antibodies. In a non-limitative example in which cortisol is the desired analyte, an anti-cortisol antibody may be used as the detection molecule 18. Other non-limitative examples of the detection molecule layer 18 include enzymes, antibodies, conjugated enzymes, conjugated antibodies, glycoproteins, deoxyribonucleic acid molecules, deoxyribonucleic acid fragments (oligomers), polymer molecules, ribonucleic acids, ribonucleic acid fragments, pharmaceutics, aptamers, hormones, and/or combinations thereof.

Embodiment(s) of the biological sensor 14 may optionally include a preservative layer 20 (shown in FIGS. 1 and 2). The preservative layer 20 may advantageously assist in prolonging the shelf life of the biological sensor 14. Without being bound to any theory, it is believed that the preservative layer 20 may advantageously preserve the function of the detection molecule layer 18. In an embodiment, while the sensor 14 is substantially dehydrated, the preservative layer 20 may substantially maintain an amount of water around the detection molecule(s) 18. It is believed that the water provided by the preservative layer 20 may substantially support the 3D conformation of the detection molecule(s) 18 and may substantially prevent denaturing of the detection molecule(s) 18. In an embodiment, the preservative layer 20 includes, but is not limited to carbohydrates, chaperone proteins, humectants (a non-limitative example of which includes polyethylene glycol having a molecular weight of about 300 kDa), pectin, amylopectin, gelatin, sol gels, hydrogels, salts, and/or mixtures thereof.

Another example of another optional layer that may be used in the biological sensor 14 is a protective/passivation layer 24, as shown in FIG. 2. The protective layer 24 may be made up of carbohydrates, humectants, pectin, amylopectin, gelatin, sol gels, hydrogels, and/or mixtures thereof. It is to be understood that generally the protective layer 24 may further protect and preserve the function of the detection molecules 18, in part, by substantially limiting water loss from the sensor 14 and by substantially limiting its exposure to UV light and/or air. Still further, the protective layer 24 may allow the sensor 14 to be substantially rapidly rehydrated upon exposure to a desired sample.

Generally, embodiment(s) of the biological sensor 14 may include a self-assembled monolayer 16 and/or a covalent attachment layer 22 to substantially enhance adhesion of the detection molecule layer 18 to the substrate 12. Further, it is to be understood that the addition of the preservative layer 20 and/or the protective layer 24 may advantageously allow the sensor 14 to remain substantially stable under ambient storage conditions. Still further, the preservative layer 20 and/or the protective layer 24 may serve to substantially preserve the function of the detection molecule layer 18 by substantially maintaining the functionality and conformation of the molecules of the detection layer 18.

Referring now to FIG. 3, an embodiment of the diagnostic device 10 or system 100 is shown. Specifically, each of the plurality of biological sensors 14 may be dispensed in a separate channel, row, or column 26 located on the substrate 12.

Generally, an embodiment of a method for forming device 10/system 100 includes dispensing layer(s) on a substrate 12, for example, a plurality of layers 16, 18, 20,22, 24 on substrate 12. The embodiment of the method for forming the device 10 shown in FIG. 3 includes dispensing five layers 16, 18, 20, 22, and 24 on the substrate 12. It is to be understood that each sensor 14 in each channel 26 may be configured to detect one or more parameters that is/are different from parameter(s) detected by each of the other sensors 14. Therefore, each sensor 14 may contain different layer materials and/or a different configuration of the layers 16,18,20,22, 24.

Each of the layers 16, 18, 20, 22, and 24 may be dispensed using drop generating technology. Drop generating technology may allow for substantially precise placement of the drops on the substrate 12. It is to be understood, however, that the precision of drop placement may be dependant, at least in part, upon the system used to hold and move the dispensed fluid. In a non-limitative example using drop generating technology, the precision of the drop placement is less than about 1 μm.

A non-limitative example of suitable drop generating technology includes an ejector head having one or more drop generators, which include a drop ejector in fluid communication with one or more reservoirs, and at least one orifice through which the discrete droplet(s) is eventually ejected. The elements of the drop generator may be electronically activated to release the fluid drops. It is to be understood that the drop generators may be positioned as a linear or substantially non-linear array, or as an array having any two dimensional shape, as desired.

An electronic device or electronic circuitry may be included in the ejector head as thin film circuitry or a thin film device that define drop ejection elements, such as resistors or piezo-transducers. Still further, the electronic device may include drive circuitry such as, for example, transistors, logic circuitry, and input contact pads. In one embodiment, the thin film device includes a resistor configured to receive current pulses and to generate thermally generated bubbles in response. In another embodiment, the thin film device includes a piezo-electrical device configured to receive current pulses and to change dimension in response thereto.

It is to be understood that the electronic device or circuitry of the ejector head may receive electrical signals and in response, may activate one or more of the array of drop generators. Each drop generator is pulse activated, such that it ejects a discrete droplet in response to receiving a current or voltage pulse. Each drop generator may be addressed individually, or groups of drop generators may be addressed substantially simultaneously. Some non-limitative examples of drop generating technology include continuous inkjet printing techniques or drop-on-demand inkjet printing techniques. Suitable examples of continuous inkjet printing techniques include, but are not limited to thermally, mechanically, and/or electrostatically stimulated processes, with electrostatic, thermal, and/or acoustic deflection processes, and combinations thereof. Suitable examples of drop-on-demand inkjet printing techniques include, but are not limited to thermal inkjet printing, acoustic inkjet printing, piezo electric inkjet printing, and combinations thereof.

To form the sensors 14 depicted in FIG. 3, self-assembled monolayers 16 are dispensed via a drop generating technique at various predetermined areas (a non-limitative example of which includes substantially isolated channels 26) on the substrate surface 13. Covalent attachment layers 22 are dispensed on each of the self-assembled monolayers 16. Detection molecule layers 18 are dispensed on each of the covalent attachment layers 22, preservation layers 20 are dispensed on each of the detection molecule layers 18, and protective layers 24 are dispensed on each of the preservation layers 20. It is to be understood that each additional layer 18, 20, 22, 24 may be dispensed such that it covers all or a portion of the previously established layer 16, 18, 20, 22, 24.

In an embodiment, the layers 16, 18, 20, 22, 24 may be dispensed as drops/droplets on the substrate surface 13 and/or on the other layer(s). In an embodiment, the drop sizes may be sub-pico liter volumes of fluid established with a spatial resolution that varies depending, at least in part, on the accuracy of the equipment used. In an embodiment, the spatial resolution may be up to about 3000 dpi. In one non-limitative example, the spatial resolution is about 2400 dpi. Generally the drops have a size ranging between about 10 femto liters and about 200 pico liters. The drops of fluid in one layer may be a build-up of a fluid to achieve the desired density and/or surface coverage. In an embodiment of the sensor 14 having multiple layers, each layer 16,18, 20, 22, 24 may have a different volume of a different fluid, the volumes defined, in part, by the number of dispensed drops and the volume of each drop.

The small volume of drops contained in each layer 16, 18, 20, 22, 24 advantageously substantially reduces chemical reaction and incubation periods typical of traditional assays, in part, because the distance through which the molecules diffuse is small (e.g. the mass transport through pico liter sized drops is substantially faster than through a micro liter sized drop).

It is to be understood that each layer 16, 18, 20, 22, 24 is dispensed at a predetermined area(s) on the substrate surface 13. In an embodiment, the predetermined area is defined so the layers 16, 18, 20, 22, 24 are dispensed on the substrate 12 such that they touch and/or overlap, as depicted in the figures. The digital image control of drop generating technology (a non-limitative example of which is inkjet printing) advantageously permits for dispensing multiple fluids in various channels 26 on the substrate surface 13 in a pattern, at a single or specific area, or across substantially the entire surface 13, as desired. Non-limitative examples of suitable patterns that the biological sensors 14 may be formed in on the surface 13 include stripes, text patterns, graphical images, and/or combinations thereof. One example of an array has hundreds of biological sensors 14 on a device that is the size of a credit card.

The inkjet printing allows for the dispensing of the multiple layers of the same or different fluids onto the same physical location (predetermined area) of the substrate 12 at controlled times. For example, the selected layers 16,18, 20, 22, and/or 24 may be dispensed substantially simultaneously with or without drying time between dispense processes. In an alternate embodiment, the selected layers 16, 18, 20, 22 and/or 24 may be dispensed sequentially. The time between drop dispensing may be modulated between substantially simultaneous to time periods (non-limitative examples of which include seconds, minutes, hours, days, etc.) lapsing between dispenses. The time for dispensing may be dependant, at least in part, upon the application and equipment configuration used.

Further, the controlled timing of drop generator dispensing allows the chemical reaction kinetics and synthesis to also occur in a controlled manner on the substrate 12, in part, because the first order concentration of reactants and products is controlled with substantially minor mass transport limitations.

Sensor 14 conformation and orientation on the surface 13 may advantageously be controlled, in part, by controlling the drying and/or evaporation rate. In an embodiment, drop drying may be controlled, in part, by dispensing the different layers at advantageous times. A non-limitative example of advantageously timing the dispensing of the layers 16, 18, 20, 22, 24 includes first dispensing the self-assembled monolayer 16 and the covalent attachment layer 22 on the substrate 12 and allowing them to sit for a desired time. It is to be understood that the self-assembled monolayer 16 and the covalent attachment layer 22 may be substantially wet or substantially dry when the detection molecule layer 18 is dispensed thereon. After the detection molecule layer 18 is dispensed, and as it is drying, the preservative layer 20 may be dispensed thereon. After a desired time, the protective layer 24 may then be deposited. It is to be understood that the sensor 14 may be substantially wet or substantially dry as the protective layer 24 is added.

The drying rate(s) of the layers 16,18, 20, 22, 24 may be controlled, for example, by formulating the dispensed liquids (e.g. adding humectants) and by controlling the surrounding environment (e.g. temperature, humidity).

The dehydration of the drops advantageously forms layers 18 (and optionally 16, 20, 22, 24) that may advantageously be stable and stored under ambient conditions. This is unlike assays/devices that include wet chemicals that may require immediate use or refrigeration storage. Further, the preservation and/or protective layers 20, 24 may allow for rapid rehydration of the sensor 14 upon exposure to a desired fluid/solution/sample.

Generally, drop generating techniques are non-contact techniques. Non-contact techniques, e.g. inkjet printing, may advantageously enable surface shape and material independence and may also enable substantially contamination-free dispensing.

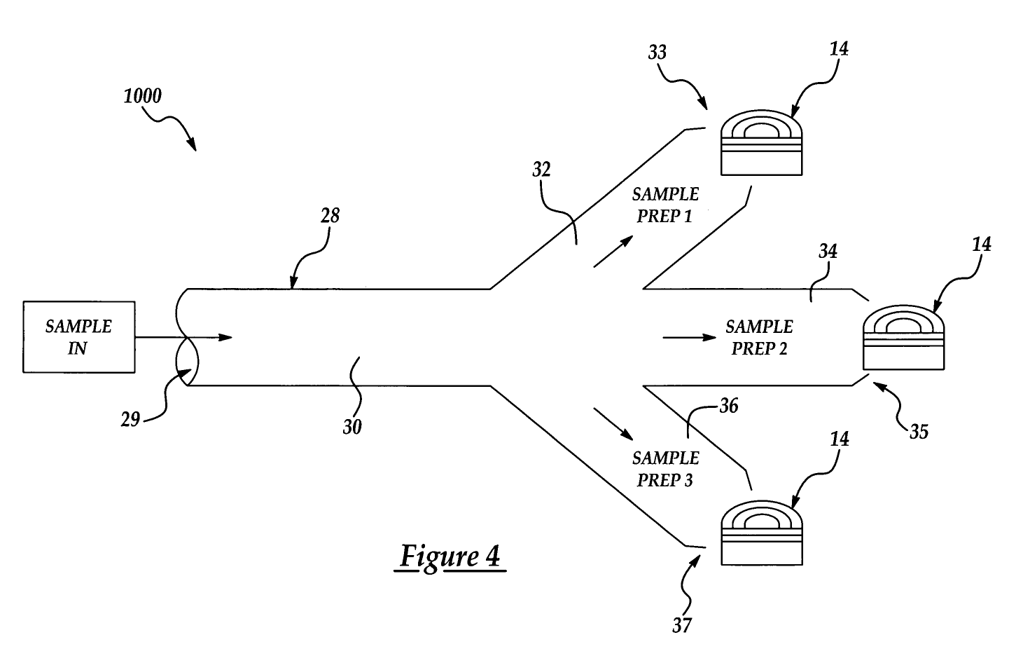

Referring now to FIG. 4, an embodiment of a microfluidic system 1000 is depicted. The microfluidic system 1000 includes a housing 28 that defines a fluid passage 30. The housing 28 also includes an entrance 29 into which a sample may be introduced.

In an embodiment, the fluid passage 30 is divided into one or more fluid conduits 32, 34, 36. It is to be understood that the three conduits 32, 34, 36 depicted in FIG. 4 are non-limitative examples, and that the microfluidic system 1000 may contain any number of conduits desirable for a particular end use. In a non-limitative example, the microfluidic system 1000 contains thousands of conduits 32, 34, 36.

Each conduit 32, 34, 36 has an area 33, 35, 37 at which an embodiment of the biological sensor 14 may be positioned. It is to be understood that area 33, 35, 37 may be at any desirable location in/adjacent to conduit 32, 34, 36. It is to be further understood that any embodiment of the biological sensor 14 as disclosed herein may be used. Each of the biological sensors 14 located at the areas 33, 35, 37 may be adapted to detect a parameter from a sample to which it is exposed. In an embodiment, each sensor 14 may be configured to detect one or more parameters that is/are different from the one or more parameters detectable by each of the other sensors 14. In a non-limitative example, a first sensor 14 is adapted to detect complementary DNA strands; while a second sensor 14 is adapted to detect a desired antibody.

It is to be understood that the sample that is introduced into the housing 28 may be divided within the housing 28 such that each portion of the sample flows through a different conduit 32, 34, 36. Further, each conduit 32, 34, 36 may be configured to prepare each portion of the sample separately, if desired. The sample preparation (if performed) in each conduit 32, 34, 36 generally occurs upstream of the sensor 14. This advantageously may allow each portion of the sample to have a specific preparation process that corresponds to each sensor 14, such that the portion of the sample may chemically react with the particular sensor 14 to detect the desired parameter(s). In an embodiment, sample preparation in each conduit 32, 34, 36 may be different from the preparation that occurs in each of the other conduits 32, 34, 36, due, in part, to the different sensors 14.

It is to be understood that each biological sensor 14 is substantially isolated in/adjacent to conduits 32, 34, 36 such that a different portion of the sample may be exposed to each sensor 14. Upon being exposed to the previously prepared sample portions, each of the biological sensors 14 detects the specific parameter for which they are configured to detect.

In a non-limitative example, the microfluidic device 1000 contains thousands of different sensors 14 located in thousands of corresponding conduits. This advantageously allows a single sample to be introduced, divided, prepared, and tested for a variety of (e.g. wellness) analyte(s)/parameter(s).

Embodiment(s) of the biological sensor 14 have many advantages, including, but not limited to the following. Embodiments of the biological sensor 14 have multiple layers 16,18,20, etc. each of which is able to perform a specific, unique function. Further, embodiments of the biological sensor 14 are dispensed to permit dehydration, thereby advantageously allowing for ambient stable storage of the sensor 14 until use. The biological sensors 14 may advantageously be used in a consumer-based diagnostic device 10 or system 100 where each sensor 14 is substantially isolated in a channel 26 and is capable of detecting a parameter that is different from each of the other sensors 14. This may advantageously allow for diagnosing and/or monitoring a variety of wellness parameters. Further, embodiment(s) of the method of forming embodiments of the biological sensor 14 allow for controlled dispensing of multiple fluids in a desired amount, on a desired area, and at a desired time. Still further, embodiments of the biological sensor 14 may be used in a microfluidic device 1000. The microfluidic device 1000 may advantageously contain a plurality (a non-limitative example of which is a thousand or more) of biological sensors 14, each of which is configured to detect a different parameter(s). Using such a device 1000, a single sample may be divided and prepared upstream for each of the particular sensors, thus advantageously allowing various parameters to be detected from the single sample.

While several embodiments have been described in detail, it will be apparent to those skilled in the art that the disclosed embodiments may be modified. Therefore, the foregoing description is to be considered exemplary rather than limiting.

What is claimed is:

1. A method of forming a biological sensor on a predetermined area of a substrate, the method comprising dispensing a plurality of layers on the predetermined area of the substrate, each of the plurality of layers formed of a substantially different fluid having a substantially different function, the dispensing being accomplished by a drop generating member.

2. The method as defined in claim 1 wherein each of the plurality of layers are formed from sub-pico liter sized drops.

3. The method as defined in claim 2 wherein the sub-pico liter sized drops are dispensed with a spatial resolution up to about 3000 dpi.

4. The method as defined in claim 1 wherein the predetermined area is defined such that the plurality of layers at least one of touch and overlap.

5. The method as defined in claim 1 wherein the plurality of layers includes at least one of a self-assembled monolayer, a covalent attachment layer, a detection molecule layer, a preservative layer, a protective layer, and combinations thereof.

6. The method as defined in claim 1 wherein the function includes at least one of self-assembling, attaching, detecting, preserving, protecting, and combinations thereof.

7. The method as defined in claim 1 wherein the plurality of layers are one of substantially simultaneously and sequentially dispensed on the predetermined area.

8. The method as defined in claim 1 wherein the drop generating member comprises at least one of continuous inkjet printing and drop-on-demand inkjet printing.

9. The method as defined in claim 8 wherein the continuous inkjet printing is accomplished by at least one of thermally, mechanically, and electrostatically stimulated processes, with at least one of electrostatic, thermal, and acoustic deflection processes, and combinations thereof; and wherein the drop-on-demand inkjet printing is accomplished by at least one of thermal inkjet printing, acoustic inkjet printing, piezo electric inkjet printing, and combinations thereof.

10. The method as defined in claim 1, wherein dispensing the plurality of layers includes dispensing a self-assembled monolayer on the predetermined area of the substrate, dispensing a covalent attachment layer on the self-assembled monolayer, dispensing a detection molecule on the covalent attachment layer, and dispensing a preservation layer on the detection molecule.

11. The method as defined in claim 1 wherein the fluid is one of a biological fluid and a non-biological fluid.

12. The method as defined in claim 1 wherein the plurality of layers includes five layers, each of the five layers including a substantially different fluid.

13. The method as defined in claim 12 wherein the predetermined area is defined such that the five layers are at least one of touching and overlapping.

14. The method as defined in claim 12 wherein each of the five layers has a substantially different function.

15. The method as defined in claim 14 wherein the functions include one of self-assembling, attaching, detecting, preserving, and protecting.

16. The method as defined in claim 12 wherein the five layers include a self-assembled monolayer, a covalent attachment layer, a detection molecule layer, a preservation layer, and a protective layer.

17. The method as defined in claim 16 wherein the self-assembled monolayer is dispensed on the predetermined area of the substrate, the covalent attachment layer is dispensed on the self-assembled monolayer, the detection molecule layer is dispensed on the covalent attachment layer, the preservation layer is dispensed on the detection molecule layer, and the protective layer is dispensed on the preservation layer.

18. The method as defined in claim 1 wherein the predetermined area defines a pattern.

19. The method as defined in claim 1 wherein the plurality of layers includes three layers, each of the three layers including a substantially different fluid.

20. The method as defined in claim 19 wherein the three layers include a detection molecule layer, one of a self-assembled monolayer and a covalent attachment layer, and one of a protective layer and a preservation layer.

21. A diagnostic device, comprising:
a substrate; and
a sensor established on a predetermined area of the substrate, the sensor including a plurality of layers, wherein each of the plurality of layers is formed of a substantially different fluid having a substantially different function, and wherein the sensor is established by a drop generating member.

22. The diagnostic device as defined in claim 21 wherein the substrate comprises at least one of glass, mylar, poly(methyl methacrylate), coated glass, gold coated glass, polystyrene, quartz, plastic materials, silicon, silicon oxides, and mixtures thereof.

23. The diagnostic device as defined in claim 21 wherein the plurality of layers includes sub-pico liter sized drops established with a spatial resolution of about 2400 dpi.

24. The diagnostic device as defined in claim 21 wherein the sensor includes at least one of a self-assembled monolayer, a covalent attachment layer, a detection molecule layer, a preservative layer, a protective layer, and combinations thereof.

25. The diagnostic device as defined in claim 24 wherein the self-assembled monolayer comprise at least one of strepavidin, biotinylated antibodies, thiols, silane coupling agents, dextran, polygels, sol gels, and mixtures thereof.

26. The diagnostic device as defined in claim 24 wherein the covalent attachment layer comprises at lease one of streptavidin, biotin, reactive end groups on silane coupling agents, and mixtures thereof.

27. The diagnostic device as defined in claim 24 wherein the detection molecule layer comprises at least one of enzymes, antibodies, conjugated enzymes, conjugated antibodies, glycoproteins, deoxyribonucleic acid molecules, deoxyribonucleic acid fragments, polymer molecules, ribonucleic acid molecules, ribonucleic acid fragments, pharmaceutics, aptamers, hormones, and combinations thereof.

28. The diagnostic device as defined in claim 24 wherein the preservative layer comprises at least one of carbohydrates, chaperone proteins, humectants, pectin, amylopectin, gelatin, sol gels, hydrogels, salts, and mixtures thereof.

29. The diagnostic device as defined in claim 24 wherein the protective layer comprises at least one of carbohydrates, humectants, pectin, amylopectin, gelatin, sol gels, hydrogels, and mixtures thereof.

30. The diagnostic device as defined in claim 21 wherein the substantially different functions include at least one of self-assembling, attaching, detecting, preserving, protecting, and combinations thereof.

31. The diagnostic device as defined in claim 21 wherein the drop generating member comprises at least one of continuous inkjet printing and drop-on-demand inkjet printing.

32. The diagnostic device as defined in claim 31 wherein the continuous inkjet printing is accomplished by one of thermally, mechanically, and electrostatically stimulated processes, with at least one of electrostatic, thermal, and acoustic deflection processes, and combinations thereof; and wherein the drop-on-demand inkjet printing is accomplished by at least one of thermal inkjet printing, acoustic inkjet printing, and piezo electric inkjet printing.

33. The diagnostic device as defined in claim 21 wherein the sensor includes a self-assembled monolayer established on the predetermined area of the substrate, a covalent attachment layer established on the self-assembled monolayer, a detection molecule established on the covalent attachment layer, a preservation layer established on the detection molecule, and a protective layer established on the preservation layer.

34. The diagnostic device as defined in claim 21 wherein the sensor includes one of a self-assembled monolayer and a covalent attachment layer established on the predetermined area of the substrate, a detection molecule established on the one of the self-assembled monolayer and the covalent attachment layer, and one of a preservation layer and a protective layer established on the detection molecule.

35. The diagnostic device as defined in claim 21 wherein the fluid is one of a biological fluid and a non-biological fluid.

36. The diagnostic device as defined in claim 21 wherein the substrate includes a plurality of channels, the diagnostic device further comprising a sensor established in each of the channels.

37. A method of using the diagnostic device as defined in claim 21, the method comprising at least one of diagnosing and monitoring at least one parameter.

38. The method as defined in claim 37 wherein the at least one parameter comprises chronic disease markers, infectious disease markers, molecular biology markers, and pharmaceutics.

39. A system for at least one of diagnosing and monitoring at least two different parameters, the system comprising:
a substrate having at least two channels defined thereon;
a first sensor established in one of the at least two channels; and
a second sensor established in the other of the at least two channels, each of the sensors including at least one layer, wherein the at least one layer is formed of a fluid having a predetermined function, each of the sensors is established by a drop generating member, and the first sensor is adapted to detect one of the at least two different parameters, and the second sensor is adapted to detect the other of the at least two different parameters.

40. The system as defined in claim 39 wherein the at least two different parameters comprise chronic disease markers, infectious disease markers, molecular biology markers, pharmaceutics, and combinations thereof.

41. The system as defined in claim 39 wherein the sensor includes at least one of a self-assembled monolayer, a covalent attachment layer, a detection molecule layer, a preservative layer, a protective layer, and combinations thereof.

42. The system as defined in claim 41 wherein the self-assembled monolayer comprises at least one of strepavidin, biotinylated antibodies, thiols, silane coupling agents, dextran, polygels, sol gels, and mixtures thereof.

43. The system as defined in claim 41 wherein the covalent attachment layer comprises at least one of streptavidin, biotin, reactive end groups on silane coupling agents, and mixtures thereof.

44. The system as defined in claim 41 wherein the detection molecule layer comprises at least one of enzymes, antibodies, conjugated enzymes, conjugated antibodies, glycoproteins, deoxyribonucleic acid molecules, deoxyribonucleic acid fragments, polymer molecules, ribonucleic acid molecules, ribonucleic acid fragments, pharmaceutics, aptamers, hormones, and combinations thereof.

45. The system as defined in claim 41 wherein the preservative layer comprises at least one of carbohydrates, chaperone proteins, humectants, pectin, amylopectin, gelatin, sol gels, hydrogels, salts, and mixtures thereof.

46. The system as defined in claim 41 wherein the protective layer comprises at least one of carbohydrates, humectants, pectin, amylopectin, gelatin, sol gels, hydrogels, and mixtures thereof.

47. The system as defined in claim 39 wherein the sensor includes at least one of a self-assembled monolayer and a covalent attachment layer established on the predetermined area of the substrate, a detection molecule established on the at least one of the self-assembled monolayer and the covalent attachment layer, and at least one of a preservation layer and a protective layer established on the detection molecule.

48. The system as defined in claim 39 wherein the drop generating member comprises at least one of continuous inkjet printing and drop-on-demand inkjet printing, and wherein the drop-on-demand inkjet printing is accomplished by at least one of thermal inkjet printing, acoustic inkjet printing, and piezo electric inkjet printing.

49. A method of testing a sample for at least two different parameters, the method comprising:
introducing a sample into a microfluidic device, the device having at least two conduits, each of the at least two conduits having a sensor positioned therein, each of the sensors including at least one layer formed of a fluid having a predetermined function, and each of the sensors is established by a drop generating member;
dividing the sample such that a first portion is introduced into one of the at least two conduits, and a second portion is introduced into the other of the at least two conduits; and
exposing the first portion of the sample to the sensor positioned in one of the at least two conduits and the second portion of the sample to the sensor positioned in the other of the at least two conduits;
wherein one of the sensors is adapted to detect one of the at least two different parameters, and the other of the sensors is adapted to detect the other of the at least two different parameters.

50. The method as defined in claim 49, further comprising preparing each of the first and second sample portions prior to exposing them to the sensors.

51. The method as defined in claim 49 wherein the at least two different parameters comprise chronic disease markers, infectious disease markers, molecular biology markers, pharmaceutics, and combinations thereof.

52. The method as defined in claim 49 wherein the sensors include at least one of a self-assembled monolayer, a covalent attachment layer, a detection molecule layer, a preservative layer, a protective layer, and combinations thereof.

53. A microfluidic system, comprising:
a housing defining a fluid passage having at least two conduits;
a first biological sensor positioned in one of the at least two conduits; and
a second biological sensor positioned in the other of the at least two conduits, the first and second biological sensors including a plurality of layers, wherein each of the plurality of layers is formed of a substantially different fluid having a substantially different function, and each of the sensors is established by a drop generating member;
wherein the first biological sensor is adapted to detect a first parameter, and the second biological sensor is adapted to detect a second parameter different from the first parameter.
